(19) United States
(12) Patent Application Publication
(10) Pub. No.: US 2023/0415198 A1
(43) Pub. Date: Dec. 28, 2023

(54) PIEZOELECTRIC ULTRASONIC TRANSDUCER AND SYSTEM

(71) Applicant: TEKNOLOGIAN TUTKIMUSKESKUS VTT OY, Espoo (FI)

(72) Inventors: Cyril KARUTHEDATH, VTT (FI); Abhilash THANNIYIL, VTT (FI); Teuvo SILLANPÄÄ, VTT (FI); Tuomas PENSALA, VTT (FI)

(21) Appl. No.: 18/035,892

(22) PCT Filed: Nov. 8, 2021
(86) PCT No.: PCT/FI2021/050755

§ 371 Date: May 8, 2023

(30) Foreign Application Priority Data
Nov. 9, 2020 (FI) 20206130

(51) Int. Cl. B06B 1/06

(52) U.S. Cl. CPC B06B 1/0666

(57) ABSTRACT

There is provided an ultrasonic transducer configured to provide passive temperature compensation for a stable operation over a wide bandwidth. The ultrasonic transducer comprises a cavity for communications of ultrasonic waves and a membrane supported movable between walls of the cavity. The membrane comprises a structural layer on a side of the membrane towards the cavity and a piezoelectric layer attached to the structural layer on an opposite side of the membrane with respect to the cavity. Temperature coefficients of Young's modulus of the structural layer and the piezoelectric layer have opposite signs for passive temperature compensation of operating frequency of the piezoelectric ultrasonic transducer.

### TECHNICAL FIELD

The present invention relates to piezoelectric ultrasonic transducers and passive temperature compensation of operating frequency of the piezoelectric ultrasonic transducers.

### BACKGROUND

Piezoelectric Micro-machined Ultrasonic Transducers (PMUTs) are highly sensitive to temperature variation due to temperature dependency of operating frequencies of the PMUTs. Temperature variation is particularly relevant for air-coupled PMUTs that have a narrow bandwidth since temperature of ambient air can vary depending the time of day and seasons. Active and passive techniques can be utilized for temperature compensation. Active techniques for temperature compensation require separate active elements such as an electronic circuit for compensating effects of temperature variation.

### SUMMARY

The scope of protection sought for various embodiments of the invention is set out by the independent claims. The embodiments, examples and features, if any, described in this specification that do not fall under the scope of the independent claims are to be interpreted as examples useful for understanding various embodiments of the invention.

According to a first aspect there is provided a piezoelectric ultrasonic transducer according to claim 1.

According to a second aspect there is provided a system according to claim 13.

### BRIEF DESCRIPTION OF THE DRAWINGS

For a more complete understanding of example embodiments of the present invention, reference is now made to the following descriptions taken in connection with the accompanying drawings in which:

FIG. 1 illustrates an example of a piezoelectric ultrasonic transducer in accordance with at least some embodiments for the present invention;

FIG. 2 illustrates an example of a system in accordance with at least some embodiments for the present invention;

FIG. 3 illustrates an example of temperature compensation performance of piezoelectric ultrasonic transducer in accordance with at least some embodiments for the present invention;

FIG. 4 illustrates an example of temperature compensation performance of piezoelectric ultrasonic transducer comprising a patterned piezoelectric layer in accordance with at least some embodiments for the present invention;

FIG. 5 illustrates patterns for a piezoelectric layer in accordance with at least some examples of the present invention; and

FIG. 6 illustrates a top view and a side view of a pattern for a piezoelectric layer in accordance with at least some examples of the present invention.

### DETAILED DESCRIPTION

In connection with ultrasonic transducers there is provided an ultrasonic transducer configured to provide passive temperature compensation for a stable operation over a wide bandwidth. The ultrasonic transducer comprises a cavity for coupling with a fluid, fluid mixture or vacuum for communications of ultrasonic waves and a membrane supported movable between walls of the cavity. The membrane comprises a structural layer on a side of the membrane towards the cavity and a piezoelectric layer attached to the structural layer on an opposite side of the membrane with respect to the cavity. Temperature coefficients of Young's modulus of the structural layer and the piezoelectric layer have opposite signs for passive temperature compensation of operating frequency of the piezoelectric ultrasonic transducer.

Ultrasonic transducers in accordance with examples described herein, may be constructed of structural parts that may be of different materials, dimensions and densities. Passive temperature compensation of the ultrasonic transducers may be achieved by contribution of two parameters:
1) Thermal expansion
2) Temperature dependency of Young's modulus

Thermal expansion is a tendency of matter to change its shape, area, volume, and density in response to a change in temperature, usually not including phase transitions. Thermal expansion of a physical structure of material may be quantified by a thermal expansion coefficient of the material. Young's modulus is a mechanical property that measures the stiffness of a solid material. It defines the relationship between stress (force per unit area) and strain (proportional deformation) in a material in the linear elasticity regime of a uniaxial deformation. Temperature expansion coefficients of materials and temperature dependency of Young's modulus for materials are well-known to a skilled person. Performance of temperature compensation in ultrasonic transducers may be measured on the basis of measuring a temperature coefficient of resonant frequency (TCF) over a temperature range.

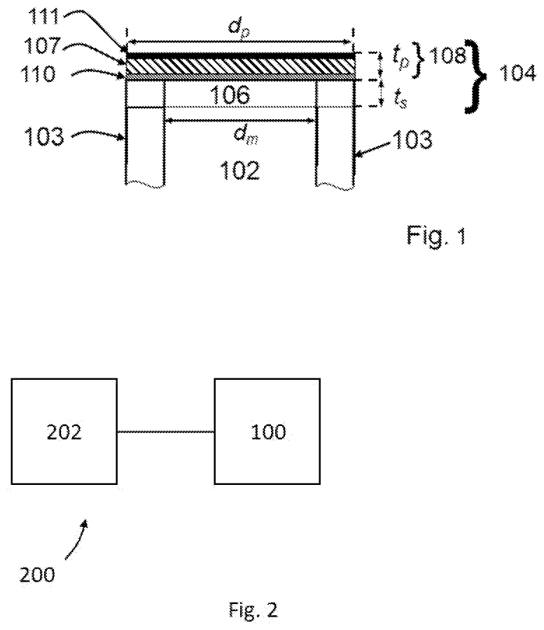

FIG. 1 illustrates an example of a piezoelectric ultrasonic transducer in accordance with at least some embodiments for the present invention. The piezoelectric ultrasonic transducer 100 comprises a cavity 102 comprising walls 103 and a membrane 104 supported between walls of the cavity for communications of ultrasonic waves. In some examples the cavity may comprise a vacuum formed within a space formed by the walls and the membrane. In some examples, the cavity may have at least one opening formed by the walls via which a fluid or a fluid mixture may enter the cavity and the fluid or the fluid mixture may be brought in contact with the membrane. Accordingly, the cavity may comprise a fluid, fluid mixture or a vacuum. The membrane 104 comprises a structural layer 106 on a side of the membrane 104 inwards to the cavity 102, and a piezoelectric layer 108 attached to the structural layer 106 on an opposite side of the membrane 104 with respect to the cavity 102. A temperature coefficient of Young's modulus of the structural layer 106 and a temperature coefficient of Young's modulus of the piezoelectric layer 108 have opposite signs for passive temperature compensation of operating frequency of the piezoelectric ultrasonic transducer. In this way stable operation of the piezoelectric ultrasonic transducer may be supported over a wide bandwidth.

In an example, a fluid or fluid mixture may be in gas phase or liquid phase. Examples of the fluids in gas phase, i.e. gases, comprise at least oxygen, hydrogen, methane, chlorine, nitrogen. Examples of the fluid mixtures in gas phase, i.e. gas mixtures, comprise air and mixtures of gases comprising one or more of air, oxygen, hydrogen, methane, chlorine and nitrogen. Examples of the fluids in liquid phase, i.e. liquids, comprise at least water, blood and urine.

The piezoelectric ultrasonic transducer 100 in accordance with at least some examples may be implemented based on the following parameters: thickness, tₛ, of the structural layer 106; thickness, tₚ, of the piezoelectric layer 108; diameter of the structural layer 106, dₘ, between the walls 103 of the cavity 102; diameter, dₚ, of the piezoelectric layer in a direction of direct distance, e.g. shortest distance, from one wall of the cavity supporting the structural layer to an opposite wall of the cavity supporting the structural layer. It should be noted that the diameter d m of the structural layer may be herein also referred to as the diameter of the membrane. The thickness, tₚ, of the piezoelectric layer and thickness, tₛ, of the structural layer may be determined in a depth direction of the cavity that is transverse to the direction of direct distance from one wall of the cavity supporting the structural layer to an opposite wall of the cavity supporting the structural layer. The dimension, dₚ, of the piezoelectric layer and dimension of the membrane, dₘ, are essentially in a direction of length of the membrane extending between the walls of the cavity or in a lateral direction. The direction of length of the membrane may be determined on the basis of a direction of a top surface of the structural layer. The top surface of the structural layer is a surface of the structural layer on a side of the structural layer, where the piezoelectric layer is positioned.

In an example configuration of the piezoelectric ultrasonic transducer 100, the thickness, tₛ, of the structural layer 106 may be from 2 μm to 10 μm.

In an example in accordance with at least some embodiments, the piezoelectric ultrasonic transducer 100 may be a micro-machined device, i.e. a piezoelectric micro-machined ultrasonic transducer, PMUT. A PMUT may be manufactured by a micrometer scale manufacturing process, where dimensions of components of the piezoelectric ultrasonic transducer may be in the order of micrometers, e.g. from 1 to 500 μm. An example of a manufacturing process comprises depositing material layers for components of the piezoelectric ultrasonic transducer on one or more Si wafers and patterning the components on the deposited material layers and etching the components from the Si wafer. The components can then be bonded together. The PMUT provides electromechanical coupling between a fluid, fluid mixture and electrical signals, whereby the PMUT may be referred to a MEMS (micro-electro-mechanical systems)-device.

In an example in accordance with at least some embodiments, the structural layer 106 comprises a silica, SiO2, layer and the piezoelectric layer 108 comprises an Aluminum Nitride (AlN) layer, Scandium Aluminum Nitride (ScAlN) layer, Lead Zirconate Titanate (PZT) layer, Lead Lanthanum Zirconate Titanate (PLZT) layer, or an Nb-doped lead zirconate titanate (PNZT) layer. It should be note that the piezoelectric layer 108 may comprise also other alloys of AlN than ScAlN and also other alloys of PZT than PLZT and PNZT. Accordingly, the piezoelectric layer 108 may comprise a layer of an alloy of AlN, such as ScAlN, or an alloy of PZT such as PLZT or PNZT, but other alloys of AlN and ScAlN are viable. The temperature coefficient of Young's modulus of SiO2 is a positive value and the temperature coefficient of Young's modulus of AlN is a negative value, whereby thermal expansion of the structural layer may cancel the thermal expansion of the piezoelectric layer.

In an example in accordance with at least some embodiments, a ratio of a diameter dₚ of the piezoelectric layer 108 to a diameter dₘ of the membrane 104 between cavity walls 103, has a value from 0.4 to 1.0. In this way it may be provided that a deformation experienced by the piezoelectric layer and a deformation experienced by the structural layer due to temperature variation are proportioned to one another for the structural layer cancelling the effect of thermal expansion of the piezoelectric layer and vice versa. If a ratio outside the range 0.4 to 1.0 is used, electromechanical coupling of the piezoelectric ultrasonic transducer 100 may be degraded. An example of the diameter of the piezoelectric layer is the dimension dₚ. An example of the diameter of the membrane 104 is the dimension dₘ.

In an example in accordance with at least some embodiments, the piezoelectric layer 108 comprises metal electrodes 110,111 separated by a layer of piezoelectric material 107, for example AlN, Scandium Aluminum Nitride (ScAlN), Lead Zirconate Titanate (PZT) or an alloy of PZT such as Lead Lanthanum Zirconate Titanate (PLZT) or Nb-doped lead zirconate titanate (PNZT). The metal electrodes and the piezoelectric material have negative signs of temperature coefficient of Young's modulus, whereby the structural layer 106 having an opposite sign, i.e. a positive sign, of the temperature coefficient of Young's modulus may cancel a thermal expansion experienced by the piezoelectric layer and vice versa.

In an example, the piezoelectric layer 108 comprises a bottom electrode 110 between the piezoelectric material 107 and the structural layer 106 and on an opposite side of the piezoelectric material the piezoelectric layer 108 comprises a top electrode 111. The bottom electrode may have a diameter dₘ in a direction of length of the membrane extending between the walls 103 of the cavity or in a lateral direction.

In an example in accordance with at least some embodiments, temperature coefficient of Young's modulus of the piezoelectric layer 108 has a negative sign and the temperature coefficient of Young's modulus of the structural layer 106 has a positive sign. In this way it may be provided that a thermal expansion experienced by the piezoelectric layer and a thermal expansion experienced by the structural layer may cancel the effect of thermal expansion of the piezoelectric layer and vice versa.

In an example in accordance with at least some embodiments, a dimension of the structural layer 106 in a depth direction of the cavity 102 has a value, where the structural layer 106 cancels the effect of thermal expansion of the piezoelectric layer 108. In an example in accordance with at least some embodiments, the piezoelectric layer 108 is patterned. The patterning provides that contribution of the piezoelectric layer to thermal expansion may be reduced which in turn reduces the total thermal expansion of the membrane 108. In an example the piezoelectric layer may be patterned by patterning the piezoelectric material 107 of the piezoelectrical layer or by patterning both the piezoelectric material and an electrode 110, a bottom electrode, between the piezoelectric layer and the structural layer.

### Example

A PMUT comprises a structural layer 106 of silica, SiO2, and a piezoelectric layer 108 of Aluminum Nitride, AlN, and the piezoelectric layer 108 is patterned. Thermal expansion of a piezoelectric layer of AlN may be almost 10× higher compared to a structural layer of SiO2. With the patterning of the piezoelectric layer, the contribution of AlN to thermal expansion may be reduced, which in turn reduces the total thermal expansion of membrane 104. Because of the effect of thermal expansion, the resonance frequency of the PMUT decreases with an increase in temperature. Accordingly, Temperature coefficient of resonance frequency (TCF) of the PMUT is negative. With the patterning of AlN, TCF is still negative but its value may be much smaller. Temperature dependency of young's modulus of SiO2 is positive and that of the AlN piezo layer is negative. When a thickness and surface area of the structural layer is greater than a thickness and surface area of the piezoelectric layer, the SiO2 is dominant for the thermal expansion of the PMUT, and the TCF is positive. At preferred dimensions (dₘ, dₚ, tₛ, tₚ) this positive effect of temperature dependency of Youngs modulus reduces or cancels negative effects due to thermal expansion and the TCF is positive. Examples of the dimensions are given in Table 1 that shows various examples of dimensions for a PMUT where temperature compensation is achieved. The Table 1 gives examples of ratios of a diameter of the piezoelectric material dₚ to a diameter the membrane dₘ, and a ratio of a diameter d_{b} of the bottom electrode to a diameter of the diameter of the membrane dₘ. The PMUT comprises a structural layer 106 of SiO2, a piezoelectric material 107 of AlN, and a bottom electrode of Molybdenum (MO), where the temperature compensation is achieved for the PMUT.

TABLE 1
examples of dimensions for a PMUT

| Resonace Frequency | | | tₛ | tₚ |
|---|---|---|---|---|
| (kHz) | dₚ/dₘ | d_{b}/dₘ | (μm) | (μm) |
| 260 | 0.70 | 0.70 | 5 | 1 |
| 398 | 0.70 | 0.70 | 8 | 1 |
| 502 | 0.65 | 0.65 | 5 | 2 |
| 1247 | 0.60 | 0.60 | 4 | 1 |
| 1565 | 0.65 | 0.90 | 5 | 1 |
| 1517 | 0.55 | 0.70 | 5 | 1 |
| 2377 | 0.90 | 0.90 | 8 | 1 |
| 2450 | 0.60 | 0.60 | 2 | 1 |
| 6234 | 1.00 | 1.00 | 5 | 1 |

It should be noted that for dₚ/dₘ=d_{b}/dₘ in Table 1, the dimensions of the piezoelectric material and the bottom electrode are the same. d_{b} refers to diameter of 110 the bottom electrode, dₚ refers to diameter of the piezoelectric material and dₘ refers to diameter of the membrane.

FIG. 2 illustrates an example of a system in accordance with at least some embodiments for the present invention. The system 200 comprises a piezoelectric ultrasonic transducer 100 according to at least some of the examples described with FIG. 1, and one or more processors 202 electromechanically connected to the piezoelectric layer 108 for transmitting and/or receiving ultrasonic waves.

In an example of transmitting the ultrasonic waves, a processor 202 may actuate the piezoelectric layer 108 of the piezoelectric ultrasonic transducer by electrical signals that cause a piezoelectric material 107 of the piezoelectric layer to vibrate and generation of ultrasonic waves. The electric signals may be generated by the system to cause generation of ultrasonic waves for purposes of various applications of the system.

In an example of receiving the ultrasonic waves, ultrasonic waves may cause vibration of a piezoelectric material 107 of the piezoelectric layer 108 and generation of electric signals that are received by a processor 202. The electric signals may be processed for purposes of various applications of the system 200, whereby processed data may be obtained for controlling one or more applications of the system.

In an example in accordance with at least some embodiments, the system 200 is an ultrasound measurement device. Examples of ultrasound measurement devices comprise at least an ultrasound imaging device, a level measurement device or a flow measurement device. Accordingly, examples of applications of the system comprise at least an ultrasound imaging, a level measurement and a flow measurement. Examples of the ultrasound imaging comprise at least medical imaging or industrial imaging. Examples of the level measurement comprise at least a measurement of a level of fluid in a container. Examples of the flow measurement comprise at least a measurement of fluid flow.

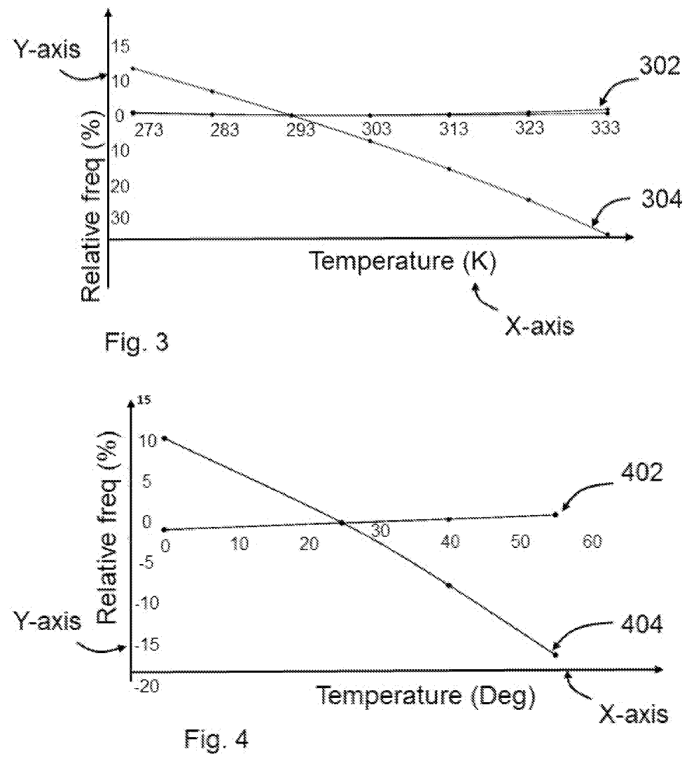

FIG. 3 illustrates an example of temperature compensation performance of a piezoelectric ultrasonic transducer in accordance with at least some embodiments for the present invention. The temperature compensation performance can be determined by a temperature coefficient of resonant frequency (TCF). The TCF indicates a graduate change of the resonant frequency with changing temperature. In FIG. 3 a relative change of the TCF is illustrated on Y-axis against temperature in Kelvins on X-axis. The relative change of the TCF is illustrated for different designs of piezoelectric ultrasonic transducers, where one of the designs is for a piezoelectric ultrasonic transducer having a temperature coefficient of Young's modulus of the structural layer 106 and a temperature coefficient of Young's modulus of the piezoelectric layer 108 of the same sign. Accordingly, the structural layer and the piezoelectric layer may both comprise a layer of AlN. The relative change of the TCF is further illustrated for designs for piezoelectric ultrasonic transducers according to at least some embodiments, where the temperature coefficient of Young's modulus of the structural layer 106 and a temperature coefficient of Young's modulus of the piezoelectric layer 108 have opposite signs. The examples of the other designs, where the temperature coefficient of Young's modulus of the structural layer 106 and a temperature coefficient of Young's modulus of the piezoelectric layer 108 have opposite signs, have tₛ of 2 μm and tₛ of 10 μm. The relative change of the TCF is illustrated over the range of temperatures from 273 K to 333 K, where the relative change of the TCFs 302 of the piezoelectric ultrasonic transducers that have opposite signs of the temperature coefficients of Young's modulus of the structural layer 106 and a temperature coefficient of Young's modulus of the piezoelectric layer 108 is substantially stable, e.g. the relative TCF change is at least less than 4% and even less than 3% over the temperature range from 273K to 333K. On the other hand the relative change of the TCF 304 of the design the piezoelectric ultrasonic transducer, where the temperature coefficients of Young's modulus of the structural layer and the piezoelectric layer have the same sign, is from 3% to 14% over the temperature range from 273K to 292 K and from 0% to −34% over the temperature range from 294 K to 333 K.

FIG. 4 illustrates an example of temperature compensation performance of a piezoelectric ultrasonic transducer comprising a patterned piezoelectric layer in accordance with at least some embodiments for the present invention. The performance is illustrated using the relative change of TCF similar to FIG. 3 on the Y-axis. The relative change of the TCF is illustrated against temperature in ° C. on X-axis. The relative change of the TCF is illustrated for two designs of piezoelectric ultrasonic transducers, where one of the designs is for a piezoelectric ultrasonic transducer having a temperature coefficient of Young's modulus of the structural layer 106 and a temperature coefficient of Young's modulus of the piezoelectric layer 108 of the same sign. Accordingly, the structural layer and the piezoelectric layer may both comprise a layer of AlN. The other design is for a piezoelectric ultrasonic transducer according to at least some embodiments, where the temperature coefficient of Young's modulus of the structural layer 106 and a temperature coefficient of Young's modulus of the piezoelectric layer 108 have opposite signs and the piezoelectric layer is patterned. The relative change of the TCF is illustrated over the range of temperatures from 0° C. to 55° C., where the relative change of the TCF 402 of the design of the piezoelectric ultrasonic transducer that has opposite signs of the temperature coefficients of Young's modulus of the structural layer 106 and the temperature coefficient of Young's modulus of the piezoelectric layer 108 that is patterned, is substantially stable, e.g. the relative TCF change is at least less than 2% and even less than 1% over the temperature range from 0° C. to 55° C. The relative change of the TCF 404 of the design, where the temperature coefficients of Young's modulus of the structural layer and the piezoelectric layer have the same sign, is from 10% to 2% within the temperature range from 0° C. to 24° C. and from 2% to −17% within the temperature range from 25° C. to ° C.

FIG. 5 illustrate patterns for a piezoelectric layer in accordance with at least some examples of the present invention. The patterns in FIG. 5 are described with reference to the items in FIG. 1. In the examples, a bottom electrode 110, a layer of piezoelectric material 107 and a top electrode 111 are arranged on top of a structural layer 106. The structural layer 106 or the membrane 104 has a diameter dₘ between the cavity walls 103, the bottom electrode has a diameter d_{b} and the layer of piezoelectric material has a diameter dₚ, such that dₘ>d_{b}>dₚ. The top electrode has a smaller diameter than dₚ. Accordingly, perimeters of each of the structural layer, the bottom electrode and the layer of piezoelectric material may be visible, when the structural layer, the bottom electrode, the piezoelectric layer and the top electrode are viewed from above according to FIG. 5. Accordingly, the structural layer has the largest dimension and the top electrode has the smallest dimension. The examples (1), (2), (3), (4) and (5) show the structural layer, the bottom electrode, the layer of piezoelectric material and the top electrode which have circular shapes as seen from the above in FIG. 5. It should be noted that also other shapes are viable such as a hexagonal, a rectangular and a square shape and the shapes of the structural layer, the bottom electrode, the layer of piezoelectric material and the top electrode may be different with respect to each other. It should be noted that a ratio of dₚ/dₘ may be different in the different examples (1), (2), (3), (4) and (5).

Examples (2), (3), (4) and (5) in FIG. 5 illustrate examples of patterns comprising projections 502, 504, 506, 508 in a direction of length of the membrane 104 extending between the walls 103 of the cavity 102. The projections affect the thermal expansion of the piezoelectric layer.

In an example, a projection 502, 504, 506, 508 is formed by the layer of piezoelectric material 107 and the bottom electrode 110 that extend away from the top electrode 111 in the direction of length of the membrane 104 extending between the walls 103 of the cavity 102. Accordingly, a projection 502, 504, 506, 508 may refer to a part of the layer of piezoelectric material and/or the bottom electrode that extends in a lateral direction from a base shape of the layer of piezoelectric material and/or the bottom electrode. It should be noted that in the examples (1), (2), (3), (4) and (5), the base shape of the layer of piezoelectric material and/or the bottom electrode may refer to a shape of the layer of piezoelectric material and/or the bottom electrode as seen from above according to the illustration of FIG. 5. The base shape of the layer of piezoelectric material 107 and/or the bottom electrode 110 may be the same as the shape of the top electrode 111 as seen from above according to the illustration of FIG. 5. Accordingly, in FIG. 5, the top electrode has a circular shape and the base shapes of the layer of the piezoelectric material and the bottom electrode have the same shape and they are also circular. It should be appreciated that other shapes of the layer of piezoelectric material, the bottom electrode and the top electrode are viable such as a hexagonal, rectangular or square shape and the base shapes of the layer of piezoelectric material and/or the bottom electrode may have different shapes with respect to each other.

In an example the projections 502, 504, 506, 508 may be evenly distributed on the perimeters of the layer of piezoelectric material and the bottom electrode. The second (2), the third (3), the fourth (4) and the fifth (5) example show examples of even distributions of the projections on the perimeters. In the second (2) example, the layer of piezoelectric material and the bottom electrode comprise two projections 502. The projections 502 are arranged on opposite sides of the perimeter of the layer of piezoelectric material and the perimeter of the bottom electrode and the projections divide each of the perimeters into two parts that have even lengths. In the third (3) example, the layer of piezoelectric material and the bottom electrode comprise three projections 504. The projections 504 are arranged evenly on the perimeters and the projections divide each of the perimeters into three parts that have even lengths. In the fourth (4) example, the layer of piezoelectric material and the bottom electrode comprise four projections 506. The projections 506 are arranged evenly on the perimeters and the projections divide each of the perimeters into four parts that have even lengths. In the fifth (5) example, the layer of piezoelectric material and the bottom electrode comprise eighth projections 508. The projections 508 are arranged evenly on the perimeters and the projections divide each of the perimeters into eight parts that have even lengths.

It should be noted that although the examples of the patterns (1), (2), (3), (4) and (5) given in FIG. 5 show that dₘ>d_{b}>dₚ, dₘ=d_{b}=dₚ or d_{b}=dₚ, dₚ>d_{b} or d_{b}>dₚ also provide that the pattern of the piezoelectric layer may reduce contribution of the piezoelectric layer to thermal expansion. Accordingly, the diameter dₚ of the piezo electric material may be equal to or higher than the diameter d_{b} of the bottom electrode, dₚ>d_{b}.

In an example the projections 502, 504, 506 may serve for clamping the piezoelectric layer 108 to a region of the piezoelectric ultrasonic transducer outside of the cavity 102 in a direction of length of the membrane 104 extending between the walls of the cavity. Accordingly, the projections may be configured to clamp the piezoelectric layer 108 to the region and the projections may be referred to clamps. Clamping the piezoelectric layer by the projections provides controlling mechanical stress of the membrane. The clamping may control mechanical stress particularly for thin and large membranes, where mechanical stress may be increased. In an example, the region may be outside the diameter dₘ of the membrane between the cavity walls. In an example, the region may be a part of the structural layer 106 that is attached to a surface of the cavity wall 103. The part of the structural layer 106 may be attached to a top surface or a side surface of the cavity wall 103 which does not form a part of the volume of the cavity. In this way the part of the structural layer 106 may be outside of the cavity 102 in a direction of length of the membrane 104 extending between the walls of the cavity.

In an example the top electrode 111 is positioned centrally with respect to the layer of piezoelectric material 107. In this way performance of the ultrasonic transducer may be supported at least in terms of controlling an offset capacitance of the ultrasonic transducer. In an example positioning the top electrode centrally with respect to the layer of piezoelectric material comprises that center points of the top electrode and the layer of piezoelectric material are at least partially aligned. The center points may be determined on surfaces of the top electrode and the layer of piezoelectric material which are extending in the lateral direction. The center points of the top electrode and the layer of piezoelectric material may be geometrical center points of the shapes of the top electrode and the layer of piezoelectric material. In an example, the layer of piezoelectric material comprises projections 502, 504, 504, 506, whereby the top electrode is positioned centrally with respect to the projections.

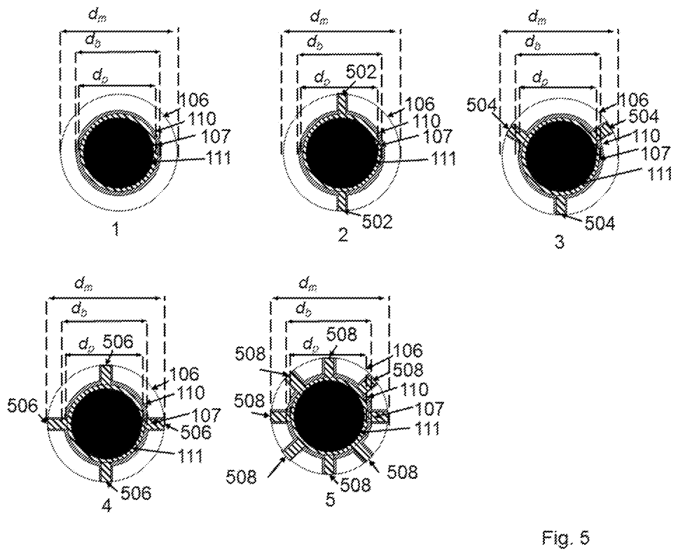

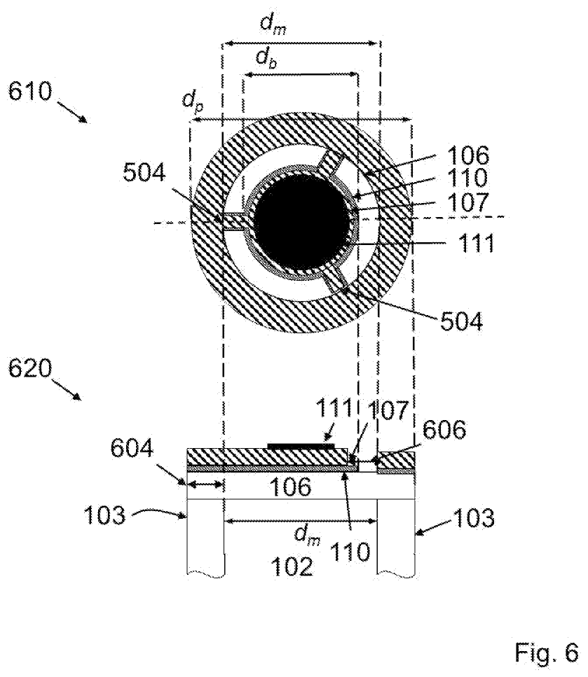

FIG. 6 illustrates a top view 610 and a side view 620 of a pattern for a piezoelectric layer in accordance with at least some examples of the present invention. The pattern is described with reference to the pattern of example (3) in FIG. 5. The pattern comprises projections 504 that are configured to clamp the piezoelectric layer 108 to a region 604 of the structural layer 106 outside of the cavity 102 in the direction of length of the membrane 104 extending between the walls 103 of the cavity. At this region 604, the layer of piezoelectric material 107 and the bottom electrode 110 may extend around the top electrode separated by a gap 606 as seen in the top view 610. The projections divide the perimeters of the layer of piezoelectric material and the bottom electrode into three parts, as seen in the top view 610. The projections extend to the region 604 of the structural layer 106 outside of the cavity 102 in the direction of length of the membrane 104 extending between the walls 103 of the cavity, and clamp the piezoelectric layer 108 to the region 604, whereby mechanical stress may be controlled. At the region 604, the piezoelectric material 107 and the bottom electrode 110 may extend annular to the top electrode as a uniform structure. It should be noted that, in other examples the piezoelectric material and the bottom electrode may extend annular to the top electrode in more than one part that are arranged at the region 604, e.g. the parts may be curved centrally around the top electrode 111.

In an example in accordance with at least some embodiments, a membrane 104 of the piezoelectric ultrasonic transducer comprises one or more gaps 606, or at least one gap. The at least one gap may form at least a part of a pattern of a piezoelectric layer. Examples of the patterns are described with FIG. 5 and FIG. 6. The at least one gap may extend through the piezoelectric layer 108 up to the structural layer 106 of the membrane. In an example the at least one gap extends between opposite ends that are separated in a longitudinal direction the gap. The longitudinal direction of the gap may be parallel to a thickness, tₚ, of the piezoelectric layer. The gap may be closed at one of the opposite ends and open at the other opposite end. The closed end of the gap may be blocked by the structural layer and the open end of the gap may penetrate the piezoelectric layer 108. On the other hand, at the sides of the gap, in a direction that is transverse to the longitudinal direction of the gap, e.g. in a direction substantially parallel with a direction of length of the membrane 104 extending between the walls of the cavity, the gap may be limited by one or more layers of the piezoelectric layer. For example, at least part of the layers of the piezoelectric layer may be positioned on top of the wall 103 of the cavity and limiting the gap in the direction that is transverse to the longitudinal direction of the gap. Referring to the example illustrated in FIG. 6, in this direction, the gap may be limited by the bottom electrode 110 and the piezoelectric material 107, that are positioned on top of the wall 103. On the other hand, in an opposite direction, e.g. in a direction that is transverse to the longitudinal direction of the gap and extending towards a center of the cavity, the gap may also be limited by the piezoelectric layer. Referring to the example illustrated in FIG. 6, in this direction, the gap may be limited by the bottom electrode 110, the piezoelectric material 107 and the top electrode 111.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

While the foregoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

1. A piezoelectric ultrasonic transducer comprising:
a cavity comprising walls and a membrane supported between the walls of the cavity for communications of ultrasonic waves, wherein the membrane comprises
a structural layer on a side of the membrane inwards to the cavity, and
a piezoelectric layer attached to the structural layer on an opposite side of the membrane with respect to the cavity,
wherein a temperature coefficient of Young's modulus of the structural layer and a temperature coefficient of Young's modulus of the piezoelectric layer have opposite signs for passive temperature compensation of operating frequency of the piezoelectric ultrasonic transducer, wherein the membrane has at least one gap through the piezoelectric layer up to the structural layer.

2. The piezoelectric ultrasonic transducer according claim 1, wherein the temperature coefficient of Young's modulus of the piezoelectric layer has a negative sign and the temperature coefficient of Young's modulus of the structural layer has a positive sign.

3. The piezoelectric ultrasonic transducer according claim 1, wherein a dimension of the structural layer in a depth direction of the cavity (102) has a value, for example from 2 μm to 8 μm, where the structural layer cancels the effect of thermal expansion of the piezoelectric layer.

4. The piezoelectric ultrasonic transducer according to claim 1, wherein a thickness, tₚ, of the piezoelectric layer is from 1 μm to 2 μm.

5. The piezoelectric ultrasonic transducer according to claim 1, wherein the structural layer comprises a SiO₂ layer and the piezoelectric layer comprises an AlN layer or a layer comprising an alloy of AlN such as a ScAlN layer, or a layer comprising PZT or a layer comprising an alloy of PZT such as a PLZT layer or a PNZT layer.

6. The piezoelectric ultrasonic transducer according to claim 1, wherein a ratio of a diameter of the piezoelectric layer to a diameter of the membrane between the walls of the cavity has a value between 0.4 and 1, for example between 0.55 to 1.

7. The piezoelectric ultrasonic transducer according to claim 1, wherein the piezoelectric layer comprises metal electrodes separated by a layer of piezoelectric material said piezoelectric material comprising AlN or an alloy of AlN such as ScAlN, or PZT or an alloy of PZT such as PLZT or PNZT.

8. The piezoelectric ultrasonic transducer according to claim 7, wherein the piezoelectric layer comprises a top electrode positioned centrally with respect to the layer of piezoelectric material.

9. The piezoelectric ultrasonic transducer according to claim 1, wherein the piezoelectric layer comprises projections in a direction of length of the membrane extending between the walls of the cavity.

10. The piezoelectric ultrasonic transducer according to claim 9, wherein the projections are configured to clamp the piezoelectric layer to a region of the piezoelectric ultrasonic transducer outside of the cavity in the direction of length of the membrane extending between the walls of the cavity.

11. The piezoelectric ultrasonic transducer according to claim 1, wherein the piezoelectric layer is patterned.

12. The piezoelectric ultrasonic transducer according to claim 1, wherein the piezoelectric ultrasonic transducer is a piezoelectric micro-machined ultrasonic transducer, PMUT.

13. A system comprising a piezoelectric ultrasonic transducer comprising:
a cavity comprising walls and a membrane supported between the walls of the cavity for communications of ultrasonic waves, wherein the membrane comprises
a structural layer on a side of the membrane inwards to the cavity, and
a piezoelectric layer attached to the structural layer on an opposite side of the membrane with respect to the cavity,
wherein a temperature coefficient of Young's modulus of the structural layer and a temperature coefficient of Young's modulus of the piezoelectric layer have opposite signs for passive temperature compensation of operating frequency of the piezoelectric ultrasonic transducer, wherein the membrane has at least one gap through the piezoelectric layer up to the structural layer; and
one or more processors connected electromechanically to the piezoelectric layer for transmitting and/or receiving ultrasonic waves.

14. The system according to claim 13, where the system is an ultrasound imaging device, a level measurement device or a flow measurement device.

15. The piezoelectric ultrasonic transducer according to claim 7, wherein the metal electrodes comprise a bottom electrode and a top electrode and a radially inner edge of the bottom electrode is exposed from underneath the piezoelectric material at the at least one gap and the diameter of the bottom electrode d_{b} is smaller than the diameter dₘ of the membrane between the cavity walls.
